(19) United States
(12) Patent Application Publication
(10) Pub. No.: US 2026/0090153 A1
(43) Pub. Date: Mar. 26, 2026

(54) CHIP PACKAGE AND LIGHT-EMITTING DEVICE

(71) Applicant: GUANGZHOU LUXVISIONS INNOVATION TECHNOLOGY LIMITED, Guangzhou City (CN)

(72) Inventor: Yi-Chih Lai, Guangzhou City (CN)

(73) Assignee: GUANGZHOU LUXVISIONS INNOVATION TECHNOLOGY LIMITED, Guangzhou City (CN)

(21) Appl. No.: 19/178,911

(22) Filed: Apr. 15, 2025

Related U.S. Application Data
(60) Provisional application No. 63/699,774, filed on Sep. 26, 2024.

(30) Foreign Application Priority Data
Dec. 26, 2024 (CN) 202411941313.7

(51) Int. Cl. H10H 20/855; H10H 20/851; H10H 20/856

(52) U.S. Cl. CPC H10H 20/855; H10H 20/8514; H10H 20/856

(57) ABSTRACT

A chip package includes a light-emitting diode chip, a reflective layer, and a microlens layer. The reflective layer surrounds the light-emitting diode chip. The microlens layer is disposed on the light-emitting diode chip and the reflective layer along a stacking direction and includes multiple microlenses arranged in an array. A light-emitting device is also provided.

### CROSS-REFERENCE TO RELATED APPLICATION

This application claims the priority benefit of U.S. provisional application Ser. No. 63/699,774, filed on Sep. 26, 2024 and China application serial no. 202411941313.7, filed on Dec. 26, 2024. The entirety of each of the above-mentioned patent applications is hereby incorporated by reference herein and made a part of this specification.

### BACKGROUND

### Technical Field

The disclosure relates to an optical element, and in particular relates to a chip package and a light-emitting device.

### Description of Related Art

The existing light-emitting diode (LED) chips predominantly emit light with a Lambertian distribution. However, optical systems such as projectors, automotive headlights, and illumination devices require highly directional light beams. Consequently, in the design of secondary optics, large-scale lenses are necessary to couple wide-angle light beams into the optical system.

### SUMMARY

A chip package and a light-emitting device, which are suitable for providing a highly directional light beam, are provided in the disclosure.

According to an embodiment of the disclosure, a chip package is provided, including a light-emitting diode chip, a reflective layer, and a microlens layer. The reflective layer surrounds the light-emitting diode chip. The microlens layer is disposed on the light-emitting diode chip and the reflective layer along a stacking direction and includes multiple microlenses arranged in an array.

According to an embodiment of the disclosure, a light-emitting device is provided, including the above-mentioned chip package.

Based on the above, the light-emitting device and chip package provided by the embodiments of the disclosure integrate multiple microlenses onto a single light-emitting diode chip through a chip manufacturing process. This configuration may optimize the light beam of the light-emitting diode chip into a highly directional light beam, which is conducive to increasing the optical coupling efficiency of the secondary optical design, reducing the number of secondary optical elements, and miniaturizing the volume of the optical system.

In order to make the above-mentioned features and advantages of the disclosure comprehensible, embodiments accompanied with drawings are described in detail below.

### BRIEF DESCRIPTION OF THE DRAWINGS

FIG. 1 is a schematic diagram showing a chip package according to some embodiments of the disclosure.

FIG. 2 is a schematic diagram showing a microlens according to a first embodiment of the disclosure.

FIG. 3 is a schematic diagram showing a microlens according to a second embodiment of the disclosure.

FIG. 4 is a schematic diagram showing a microlens according to a third embodiment of the disclosure.

FIG. 5 is a schematic diagram showing a microlens according to a fourth embodiment of the disclosure.

FIG. 6 is a schematic diagram showing a chip package according to some embodiments of the disclosure.

FIG. 7A, FIG. 7B and FIG. 7C are schematic diagrams showing light-emitting devices according to some embodiments of the disclosure.

### DETAILED DESCRIPTION OF DISCLOSED EMBODIMENTS

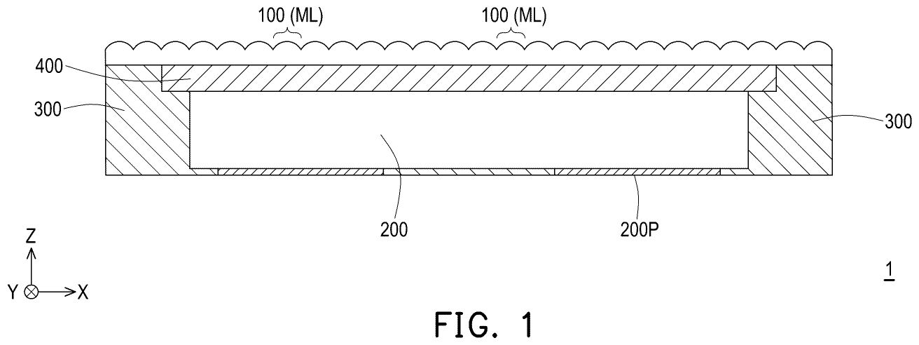

Referring to FIG. 1, FIG. 1 is a schematic diagram showing a chip package according to some embodiments of the disclosure.

The chip package 1 includes a light-emitting diode chip 200, a reflective layer 300, and a microlens layer ML. The reflective layer 300 surrounds the light-emitting diode chip 200. The microlens layer ML is disposed on the light-emitting diode wafer 200 and the reflective layer 300 along the Z direction (stacking direction), and includes multiple microlenses 100 arranged in an array. Each microlens 100 may include glass or acrylic. Accordingly, the reflective layer 300 may reflect the light with a large viewing angle from the light-emitting diode chip 200 to avoid light leakage. Multiple microlenses 100 of the microlens layer ML may further focus the light from the light-emitting diode chip 200 and the reflective layer 300 toward a front viewing angle. Through the above configuration, the brightness of the chip package 1 at a front viewing angle may be greatly improved. Therefore, it is possible to increase the optical coupling efficiency of the secondary optical design, reduce the number of secondary optical elements, and miniaturize the volume of the optical system.

In some embodiments, each microlens 100 has a width in the X direction and/or the Y direction, and the width may be less than 0.1 mm. Accordingly, one light-emitting diode chip 200 may correspond to multiple microlenses 100 to optimize the light field of the chip package 1, increase the optical coupling efficiency of the secondary optical design, reduce the number of secondary optical elements, and miniaturize the volume of the optical system. In some embodiments, each microlens 100 may be a metalens.

In one embodiment, the chip package 1 may further include a color conversion layer 400. The color conversion layer 400 includes quantum dots and is disposed between the light-emitting diode chip 200 and the microlens layer ML along the Z direction. In the X direction and the Y direction, the width of the color conversion layer 400 is greater than the width of the light-emitting diode chip 200, and the color conversion layer 400 overlaps the reflective layer 300 facing the reflective surface of the light-emitting diode chip 200, thereby ensuring that the light from the light-emitting diode chip 200 and the reflective layer 300 may all penetrate the color conversion layer 400, thereby improving the color conversion rate. In addition, the width of the color conversion layer 400 is less than the width of the microlens layer ML, so that the light penetrating the color conversion layer 400 may be focused toward a front viewing angle through the microlens layer ML.

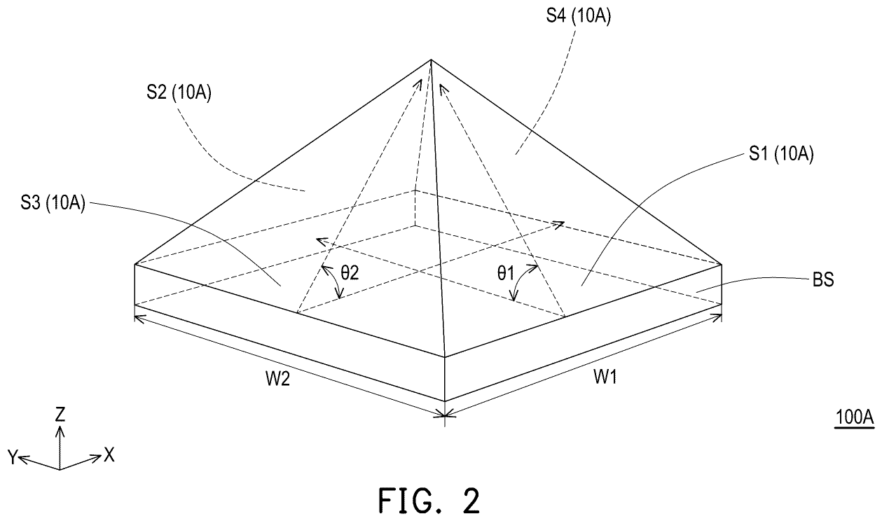

Referring to FIG. 1 and FIG. 2, FIG. 2 is a schematic diagram showing a microlens according to a first embodiment of the disclosure. In the first embodiment, each microlens 100 in FIG. 1 may be implemented as the microlens 100A shown in FIG. 2, or some of the microlenses 100 in FIG. 1 may be implemented as the microlens 100A shown in FIG. 2.

The microlens 100A of the first embodiment includes a base portion BS and a refractive structure 10A. The refractive structure 10A includes a first surface S1 and a second surface S2 opposite to each other, and a third surface S3 and a fourth surface S4 opposite to each other. The first surface S1, the second surface S2, the third surface S3 and the fourth surface S4 are triangular. The base portion BS is disposed on the X-Y plane, and the microlens 100A has a first width W1 in the X direction and a second width W2 in the Y direction. A first inclination angle θ1 is provided between the first surface S1 and the base portion BS, the first inclination angle θ1 is provided between the second surface S2 and the base portion BS, a second inclination angle θ2 is provided between the third surface S3 and the base portion BS, and the second inclination angle θ2 is provided between the fourth surface S4 and the base portion BS. The first inclination angle θ1 and the second inclination angle θ2 fall within the range of 30 degrees to 60 degrees.

In some embodiments, the first width W1 may be equal to the second width W2, and the first inclination angle θ1 and the second inclination angle θ2 may be of equal magnitude. In some embodiments, the first width W1 may not be equal to the second width W2, and the first inclination angle θ1 and the second inclination angle θ2 may be different in magnitude. Through the above configuration, the light field of the chip package 1 may be optimized, the optical coupling efficiency of the secondary optical design may be increased, the number of secondary optical elements may be reduced, and the volume of the optical system may be miniaturized.

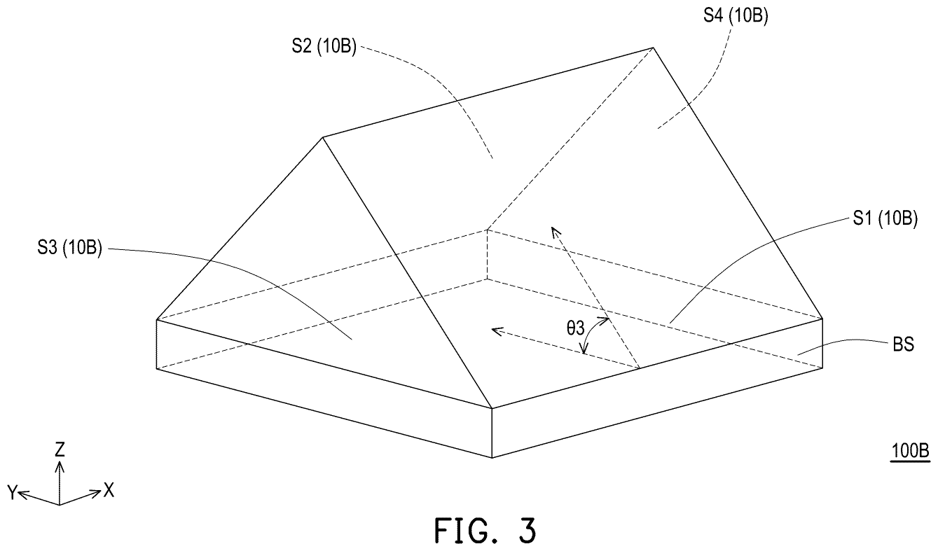

Referring to FIG. 1 and FIG. 3, FIG. 3 is a schematic diagram showing a microlens according to a second embodiment of the disclosure. In the second embodiment, each microlens 100 in FIG. 1 may be implemented as the microlens 100B shown in FIG. 3, or some of the microlenses 100 in FIG. 1 may be implemented as the microlens 100B shown in FIG. 3.

The microlens 100B of the second embodiment includes a base portion BS and a refractive structure 10B. The refractive structure 10B includes a first surface S1 and a second surface S2 opposite to each other, and a third surface S3 and a fourth surface S4 opposite to each other. The first surface S1 and the second surface S2 are rectangular, and the third surface S3 and the fourth surface S4 are triangular. The base portion BS is disposed on the X-Y plane. An inclination angle θ3 is provided between the first surface S1 and the base portion BS, the inclination angle θ3 is provided between the second surface S2 and the base portion BS, the third surface S3 is perpendicular to the base portion BS, and the fourth surface S4 is perpendicular to the base portion BS. The inclination angle θ3 may fall within the range of 30 degrees to 60 degrees. Through the above configuration, the light field of the chip package 1 may be optimized, the optical coupling efficiency of the secondary optical design may be increased, the number of secondary optical elements may be reduced, and the volume of the optical system may be miniaturized.

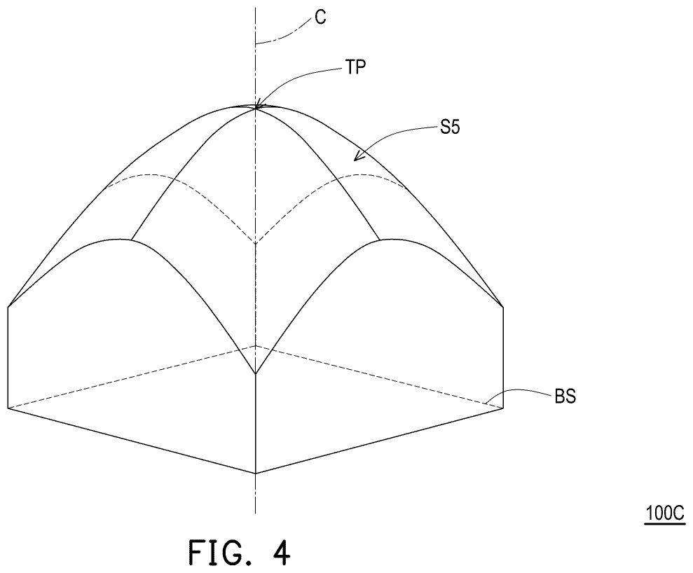

Referring to FIG. 1 and FIG. 4, FIG. 4 is a schematic diagram showing a microlens according to a third embodiment of the disclosure. In the third embodiment, each microlens 100 in FIG. 1 may be implemented as the microlens 100C shown in FIG. 4, or some of the microlenses 100 in FIG. 1 may be implemented as the microlens 100C shown in FIG. 4.

The microlens 100C of the third embodiment includes a base portion BS and a refractive surface S5. The refractive surface S5 includes an optical axis C, and the optical axis C passes through the refractive surface S5 at the vertex TP of the refractive surface S5. The radius of curvature of the refractive surface S5 at the vertex TP may fall within the range of 0.01 mm to 0.5 mm. Through the above configuration, the light field of the chip package 1 may be optimized, the optical coupling efficiency of the secondary optical design may be increased, the number of secondary optical elements may be reduced, and the volume of the optical system may be miniaturized.

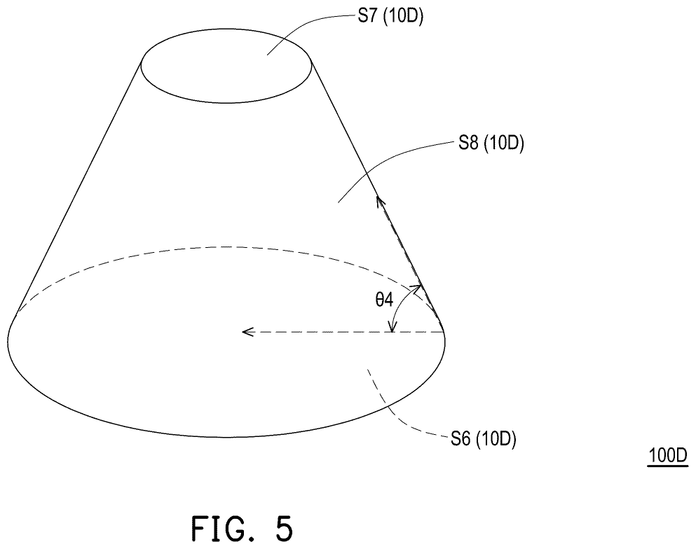

Referring to FIG. 1 and FIG. 5, FIG. 5 is a schematic diagram showing a microlens according to a fourth embodiment of the disclosure. In the fourth embodiment, each microlens 100 in FIG. 1 may be implemented as the microlens 100D shown in FIG. 5, or some of the microlenses 100 in FIG. 1 may be implemented as the microlens 100D shown in FIG. 5.

The microlens 100D of the fourth embodiment includes a refractive structure 10D. The refractive structure 10D includes a bottom surface S6, a top surface S7, and a side surface S8. An inclination angle θ4 is provided between the side surface S8 and the bottom surface S6, and the inclination angle θ4 falls within a range of 30 degrees to 60 degrees. Through the above configuration, the light field of the chip package 1 may be optimized, the optical coupling efficiency of the secondary optical design may be increased, the number of secondary optical elements may be reduced, and the volume of the optical system may be miniaturized.

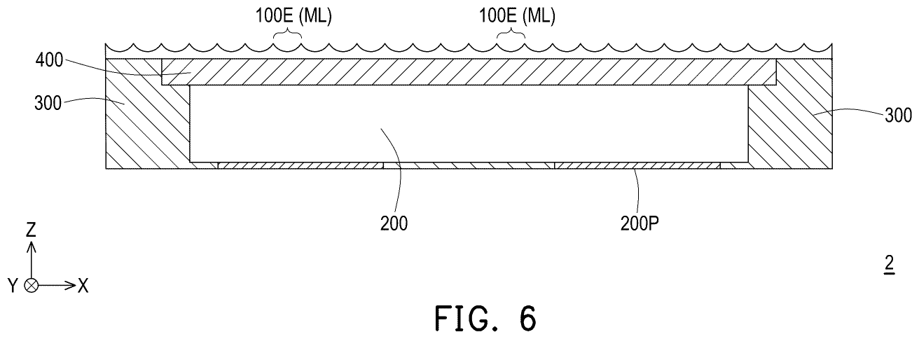

Referring to FIG. 6, FIG. 6 is a schematic diagram showing a chip package according to some embodiments of the disclosure.

The chip package 2 includes a light-emitting diode chip 200, a reflective layer 300, and a microlens layer ML. The reflective layer 300 surrounds the light-emitting diode chip 200. The microlens layer ML is disposed on the light-emitting diode chip 200 and the reflective layer 300 along the Z direction (stacking direction), and includes multiple microlenses 100E arranged in an array. Each microlens 100E may include glass or acrylic. It should be noted that each microlens 100 in FIG. 1 includes a convex surface facing the Z direction. In contrast, each microlens 100E in FIG. 6 includes a concave surface facing the Z direction. Through the above configuration, the reflective layer 300 may reflect the light with a large viewing angle from the light-emitting diode chip 200 to avoid light leakage. Multiple microlenses 100E of the microlens layer ML may further allow the light from the light-emitting diode chip 200 and the reflective layer 300 to radiate toward a large viewing angle, thereby enlarging the viewing angle of the chip package 2.

In some embodiments, each microlens 100E has a width in the X direction and/or the Y direction, and the width may be less than 0.1 mm. Accordingly, one light-emitting diode chip 200 may correspond to multiple microlenses 100E to optimize the light field of the chip package 2.

In one embodiment, the chip package 2 may further include a color conversion layer 400. The color conversion layer 400 includes quantum dots and is disposed between the light-emitting diode chip 200 and the microlens layer ML along the Z direction. In the X direction and the Y direction, the width of the color conversion layer 400 is greater than the width of the light-emitting diode chip 200, and the color conversion layer 400 overlaps the reflective layer 300 facing the reflective surface of the light-emitting diode chip 200, thereby ensuring that the light from the light-emitting diode chip 200 and the reflective layer 300 may all penetrate the color conversion layer 400, thereby improving the color conversion rate. In addition, the width of the color conversion layer 400 is less than the width of the microlens layer ML, so that the light penetrating the color conversion layer 400 may be radiated toward a large viewing angle through the microlens layer ML.

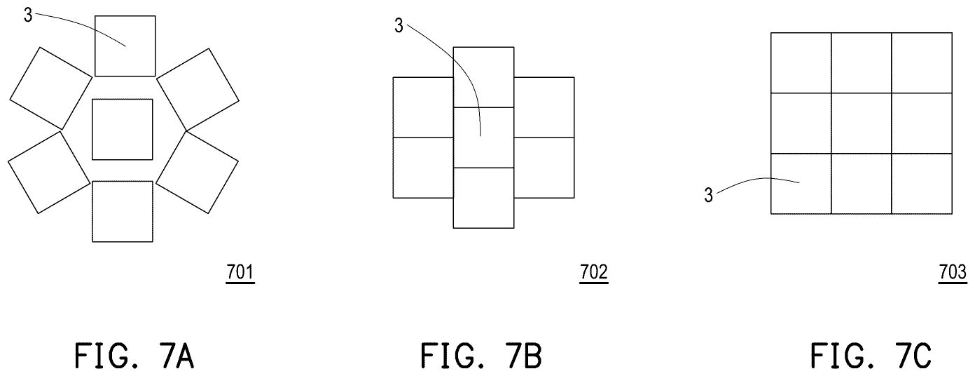

Referring to FIG. 7A, FIG. 7B and FIG. 7C, FIG. 7A, FIG. 7B and FIG. 7C are schematic diagrams showing light-emitting devices according to some embodiments of the disclosure.

According to an embodiment, as shown in FIG. 7A, a light-emitting device 701 may include multiple chip packages 3. The chip package 3 may be implemented by the chip package of any of the above embodiments.

According to an embodiment, as shown in FIG. 7B, a light-emitting device 702 may include multiple chip packages 3. The chip package 3 may be implemented by the chip package of any of the above embodiments.

According to an embodiment, as shown in FIG. 7C, a light-emitting device 703 may include multiple chip packages 3. The chip package 3 may be implemented by the chip package of any of the above embodiments.

Based on the above, the light-emitting device and chip package provided by the embodiments of the disclosure integrate multiple microlenses onto a single light-emitting diode chip through a chip manufacturing process. This configuration may optimize the light beam of the light-emitting diode chip into a highly directional light beam, which is conducive to increasing the optical coupling efficiency of the secondary optical design, reducing the number of secondary optical elements, and miniaturizing the volume of the optical system.

What is claimed is:

1. A chip package, comprising:
a light-emitting diode chip;
a reflective layer, surrounding the light-emitting diode chip; and
a microlens layer, disposed on the light-emitting diode chip and the reflective layer along a stacking direction and comprising a plurality of microlenses arranged in an array.

2. The chip package according to claim 1, wherein each of the microlenses comprises a refractive surface, the refractive surface comprises an optical axis, the optical axis passes through the refractive surface at a vertex of the refractive surface, a radius of curvature of the refractive surface at the vertex falls within a range of 0.01 mm to 0.5 mm.

3. The chip package according to claim 1, wherein each of the microlenses has a width in a direction perpendicular to the stacking direction, the width is less than 0.1 mm.

4. The chip package according to claim 1, further comprising a color conversion layer, disposed between the light-emitting diode chip and the microlens layer, wherein in a direction perpendicular to the stacking direction, a width of the color conversion layer is greater than a width of the light-emitting diode chip and less than a width of the microlens layer.

5. The chip package according to claim 1, wherein each of the microlenses comprises a refractive structure, the refractive structure comprises a first surface and a second surface opposite to each other and a third surface and a fourth surface opposite to each other, the first surface and the second surface have a first inclination angle, the third surface and the fourth surface have a second inclination angle.

6. The chip package according to claim 5, wherein the first inclination angle and the second inclination angle fall within a range of 30 degrees to 60 degrees.

7. The chip package according to claim 5, wherein the first inclination angle and the second inclination angle are of equal magnitude.

8. The chip package according to claim 5, wherein the first inclination angle and the second inclination angle are different in magnitude.

9. The chip package according to claim 5, wherein the first surface to the fourth surface are triangular.

10. The chip package according to claim 5, wherein the first surface and the second surface are rectangular, and the third surface and the fourth surface are triangular.

11. The chip package according to claim 1, wherein each of the microlenses comprises a refractive structure, the refractive structure comprises a bottom surface, a top surface, and a side surface, wherein an inclination angle is provided between the side surface and the bottom surface, and the inclination angle falls within a range of 30 degrees to 60 degrees.

12. The chip package according to claim 1, wherein the microlenses comprise metalenses.

13. The chip package according to claim 1, wherein each of the microlenses comprises a convex surface facing the stacking direction.

14. The chip package according to claim 1, wherein each of the microlenses comprises a concave surface facing the stacking direction.

15. A light-emitting device, comprising the chip package according to claim 1.
